(19) United States
(12) Patent Application Publication
(10) Pub. No.: US 2025/0275055 A1
(43) Pub. Date: Aug. 28, 2025

(54) NOVEL HIGH-SPEED VIA IMPEDANCE MATCHING METHODOLOGY USING LOW DIELECTRIC CONSTANT BACKDRILL FILLING MATERIAL

(71) Applicant: Cisco Technology, Inc., San Jose, CA (US)

(72) Inventors: David Nozadze, San Jose, CA (US); Mike Sapozhnikov, San Jose, CA (US); Sayed Ashraf Mamun, San Jose, CA (US); Amendra Koul, San Francisco, CA (US); Wenbin Ma, Shanghai (CN); Kartheek Nalla, Milpitas, CA (US)

(21) Appl. No.: 18/970,046

(22) Filed: Dec. 5, 2024

Related U.S. Application Data
(60) Provisional application No. 63/557,705, filed on Feb. 26, 2024.

(51) Int. Cl. H05K 1/02

(52) U.S. Cl. CPC H05K 1/0251; H05K 1/024; H05K 2201/09627

(57) ABSTRACT

A process for improving or reducing impedance mismatches between VIAs and traces for signal frequencies at 56 GHZ and greater by using a lower dk material for backdrill filling. By reducing such impedance mismatches, which in other words results in reducing such mismatches, the performance result is a reduction in signal reflections. In some cases, the signal reflection reduction is significant.

### CROSS-REFERENCE TO RELATED APPLICATION

This application is a non-provisional application of and claims the benefit of and priority to U.S. Provisional Patent Application No. 63/557,705 filed Feb. 26, 2024, entitled “Novel High-Speed Via Impedance Matching Methodology Using Low Dielectric Constant Backdrill Filling Material”, with Attorney Docket No. 0370.7939P/1044405, the entire disclosure of which is incorporated by reference herein in its entirety.

### TECHNICAL FIELD

The present disclosure relates to circuit boards and, more particularly, to circuit boards that have improved impedance matching between traces and VIAs.

### BACKGROUND

The rapid growth of artificial intelligence technologies are driving data centers with higher bandwidth requirements with increasingly higher data rates. With increasing data rates fundamental frequencies increase (for 224 Gbps PAM4 signaling at approximately 56 GHz) and margins are becoming smaller and smaller. One of the performances limiting factors are reflections caused by mismatching of impedances of PCB transition VIAs and traces (connecting to VIAs). These mismatches are causing: 1) high return loss resulting in reflections; and 2) resonances appearing in insertion loss at higher frequencies causing additional reflections.

Conventional solutions and methodologies do not address large impedance mismatches between VIAs and traces that are caused by high dielectric backdrill material. Thus, there is a need to improve the transition of a VIA to a trace to reduce reflections and avoid a system failure.

### BRIEF DESCRIPTION OF THE DRAWINGS

FIG. 1 is a schematic side view of an embodiment of a printed circuit board (PCB) showing a high-speed VIA according to the techniques disclosed herein.

FIG. 2 is a graph illustrating the insertion loss of a VIA structure with different backdrill materials having different dielectric constants.

FIG. 3 is a graph illustrating the return loss of a VIA structure with different backdrill materials having different dielectric constants.

FIG. 4A is a top perspective view of an embodiment of a PCB according to the techniques disclosed herein.

FIG. 4B is a side view of the PCB illustrated in FIG. 4A.

FIG. 5 is a top perspective view of the PCB illustrated in FIG. 4A having been separated into two pieces to show inner components of the PCB.

FIG. 6A is a top perspective view of the PCB illustrated in FIG. 4A showing an internal view of the PCB.

FIG. 6B is a side view of the PCB illustrated in FIG. 6A.

FIG. 7A is a top perspective view of the PCB illustrated in FIG. 6A showing an embodiment of a drill bit that can be used to backdrill the VIA.

FIG. 7B is a side view of the PCB and drill bit illustrated in FIG. 7A.

FIG. 8A is a top perspective view of the PCB illustrated in FIG. 7A showing the drill bit engaged with the VIA.

FIG. 8B is a side view of the PCB and drill bit illustrated in FIG. 8A.

FIG. 9A is a top perspective view of the PCB illustrated in FIG. 8A showing the drill bit in a position in which the drill bit has been advanced into the VIA and has removed plating from the VIA.

FIG. 9B is a side view of the PCB and drill bit illustrated in FIG. 9A.

FIG. 10A is a top perspective view of the PCB illustrated in FIG. 9A showing the backdrilled VIA.

FIG. 10B is a side view of the PCB illustrated in FIG. 10A.

FIG. 11A is a top perspective view of the PCB illustrated in FIG. 10A showing a supplying device providing a filling material into the backdrilled portion of the VIA.

FIG. 11B is a side view of the PCB illustrated in FIG. 11A.

FIG. 12A is a top perspective view of the PCB illustrated in FIG. 11A showing the filling material in both the backdrilled portion of the VIA and the non-backdrilled portion of the VIA.

FIG. 12B is a side view of the PCB illustrated in FIG. 12A.

FIG. 13A is a top perspective view of the PCB illustrated in FIG. 12A showing the filling material completely filling the VIA.

FIG. 13B is a side view of the PCB illustrated in FIG. 13A.

### DETAILED DESCRIPTION

### Overview

The problems with related art PCBs are addressed by the techniques disclosed herein. One of the main contributors to impedance mismatches between VIAs and traces is when a high dielectric constant (“dk”) backdrill material is used in a VIA.

### Example Embodiments

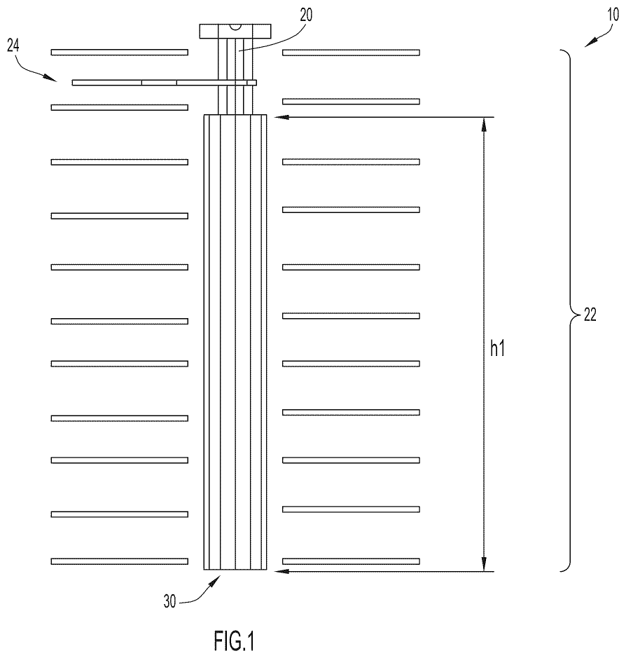

In PCB manufacturing, high-speed VIAs are backdrilled and the VIA hole is filled with a high dk material. Referring to FIG. 1, a cross-sectional schematic view of a high-speed VIA in a PCB is illustrated. In this implementation, the PCB 10 includes a VIA 20, which can be a high-speed VIA, and several ground layers 22 with core or prepreg layers therebetween. The PCB 10 includes a high-speed trace 24 that is electrically connected to the VIA 20. The VIA 20 has been backdrilled to a backdrill height “h1”. In one implementation, the backdrill height “h1” is 104 mil. After the backdrilling process, the VIA 20 is filled with a filling material 30, which in one implementation can be a resinous material.

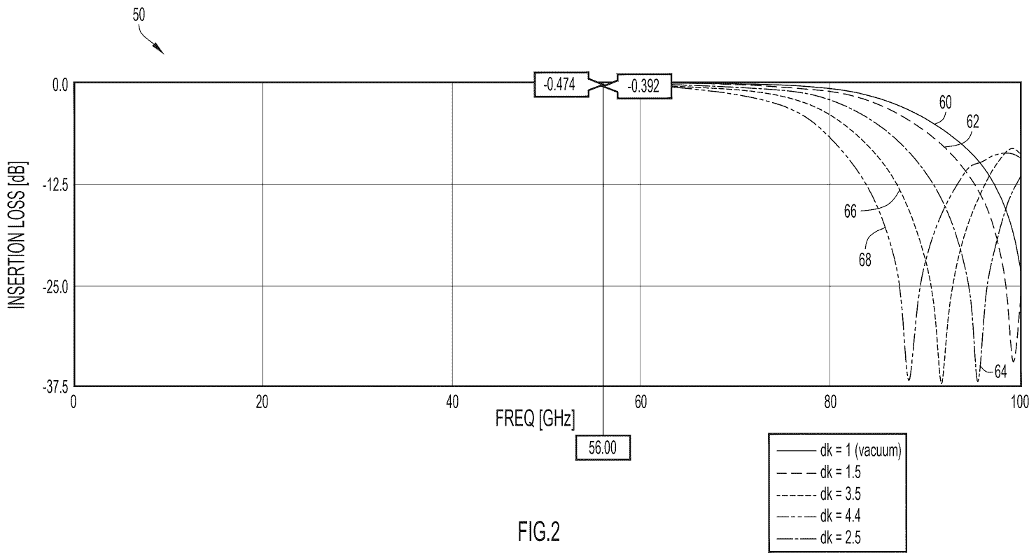

Turning to FIG. 2, a graph illustrating the insertion loss of a VIA structure with backdrill materials having different dielectric constants is shown. The graph 50 shows the measured relationship between insertion loss in dB and signal frequency in GHz. In particular, the graph 50 shows how insertion loss changes when materials with different dk properties are used for backdrill filling. A lower dk material results in improved insertion loss at higher frequencies.

Graph 50 illustrates five different lines, each of which is a measurement of a different dk material in a VIA that has a diameter of 27.9 mil. In particular, line 60 is for a vacuum (dk=1) in the VIA with no backdrill filling material present. At a frequency of 56 GHz, the measured insertion loss for dk=1 is −0.35 dB. Line 62 is for a material having a dk of 1.5. At a frequency of 56 GHz, the measured insertion loss for the dk of 1.5 material is −0.39 dB. Line 64 is for a material having a dk of 2.5. At a frequency of 56 GHz, the measured insertion loss for the dk of 2.5 material is −0.47 dB. Line 66 is for a material having a dk of 3.5. At a frequency of 56 GHZ, the measured insertion loss for the dk of 3.5 material is −0.57 dB. Line 68 is for a material having a dk of 4.4. At a frequency of 56 GHz, the measured insertion loss for the dk of 4.4 material is −0.67 dB. The foregoing measured insertion loss data is shown in Table 1 below.

TABLE 1

| | | | | | dk = 1 |
|---|---|---|---|---|---|
| | dk = 4.4 | dk = 3.5 | dk = 2.5 | dk = 1.5 | (vacuum) |
| IL @ 56 | −0.67 | −0.57 | −0.47 | −0.39 | −0.35 |
| GHz (in dB) | | | | | |

The details of some of the measurements shown in FIG. 2 are set forth in the following table. As shown in Table 2, as the dk characteristic of the backdrill material or filling material decreases, the resonance frequency increases. While the material having a dk of 4.4 has a measured resonance frequency of 88.3, which reflects a resonance loss, the material having a dk of 1.5 has a measured resonance frequency of 99 GHz, which is equivalent to a vacuum (dk=1) in the VIA, which is when no filling material is present in the VIA.

TABLE 2

| | | | | | dk = 1 |
|---|---|---|---|---|---|
| | dk = 4.4 | dk = 3.5 | dk = 2.5 | dk = 1.5 | (vacuum) |
| Resonance | 88.3 | 91.7 | 95.5 | 99 | 99 |
| Frequency | | | | | |
| (GHz) | | | | | |

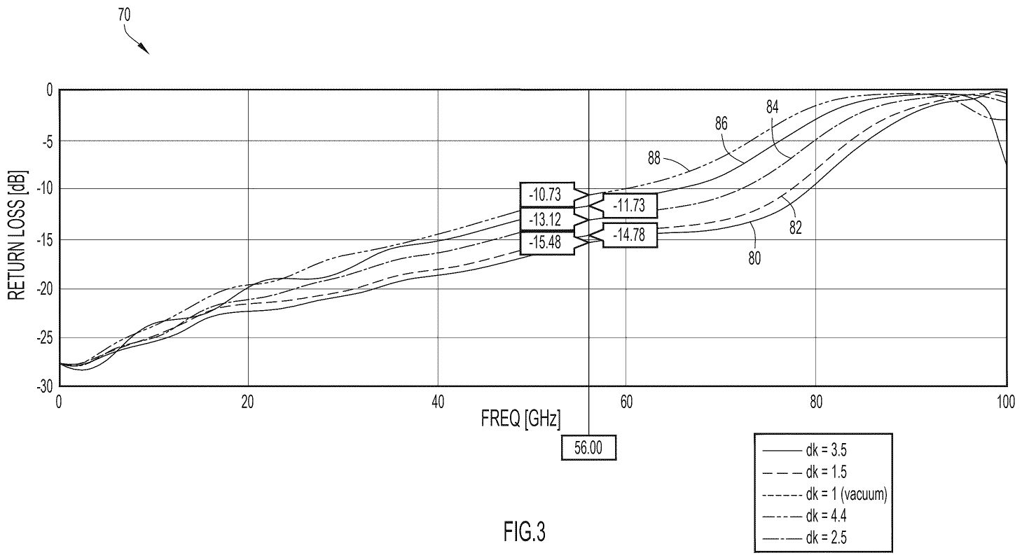

Turning to FIG. 3, a graph illustrating the return loss of a VIA structure with backdrill materials having different dielectric constants is shown. The graph 70 shows the measured relationship between return loss in dB and signal frequency in GHz. In particular, the graph 70 shows how return loss changes when materials with different dk properties are used for backdrill filling. A lower dk material results in improved return loss at higher frequencies.

Graph 70 illustrates five different lines, each of which is a measurement of a different dk material in a VIA that has a diameter of 27.9 mil. In particular, line 80 is for a vacuum (dk=1) in the VIA with no backdrill filling material present. At a frequency of 56 GHz, the measured return loss for dk=1 is −15.48 dB. Line 82 is for a material having a dk of 1.5. At a frequency of 56 GHz, the measured return loss for the dk of 1.5 material is −14.78 dB. Line 84 is for a material having a dk of 2.5. At a frequency of 56 GHZ, the measured return loss for the dk of 2.5 material is −13.12 dB. Line 86 is for a material having a dk of 3.5. At a frequency of 56 GHz, the measured return loss for the dk of 3.5 material is −11.73 dB. Line 88 is for a material having a dk of 4.4. At a frequency of 56 GHz, the measured return loss for the dk of 4.4 material is −10.73. The foregoing measured return loss data is shown in Table 3 below.

TABLE 3

| | | | | | dk = 1 |
|---|---|---|---|---|---|
| | dk = 4.4 | dk = 3.5 | dk = 2.5 | dk = 1.5 | (vacuum) |
| RL @ 56 | −10.73 | −11.73 | −13.12 | −14.78 | −15.48 |
| GHz (in dB) | | | | | |

As shown in FIG. 3, the return loss is much better when a lower dk material is used as the filling material in the VIA. For example, at approximately 56 GHZ, the return loss is approximately 4 dB to 5 dB better if a lower dk material, such as a material having a dk of 1.5, is used as compared to a higher dk material, such as a material having a dk of 4.4.

The techniques described herein relate to improving or reducing impedance mismatches between VIAs and traces for signal frequencies at 56 GHZ and greater by using a lower dk material for the backdrill filling material. By reducing such impedance mismatches, the performance result is a reduction in signal reflections. In some cases, the signal reflection reduction is significant.

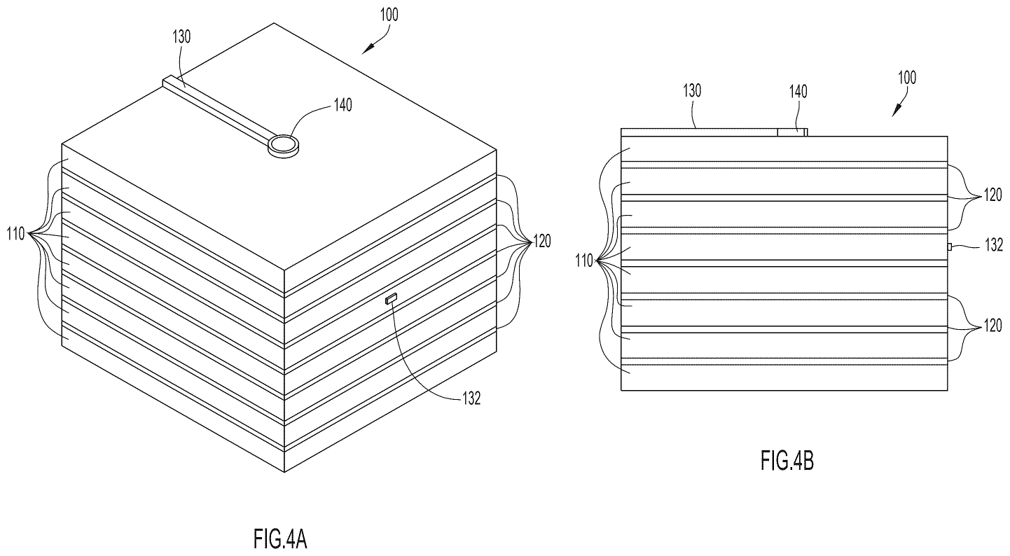

Turning to FIGS. 4A and 4B, a top perspective view and a side view, respectively, of an embodiment of a PCB according to the techniques disclosed herein are illustrated. In this embodiment, PCB 100 includes several core or prepreg layers 110, each of which is spaced apart from an adjacent layer 110 by one of several ground or power planes 120. The layers and planes can be referred to alternatively as planes or layers. PCB 100 includes high-speed traces 130 and 132 that are located at different vertical levels in the PCB 100. In FIGS. 4A and 4B, only an end of high-speed trace 132 is visible.

In this embodiment, PCB 100 also includes a VIA 140 that extends through layer 110 and plane 120. The inner part of the VIA 140 includes a non-conductive material, such as air, and an internal plating layer, which is a conductive plating, that extends along the inner surface of the VIA 140. The conductive plating of the VIA 140 connects each layer of the PCB 100. In one implementation, the conductive plating is provided by electroplating. In another implementation, the conductive plating is provided by placing metallic cylinders, such as copper cylinders, into the drilled VIA hole.

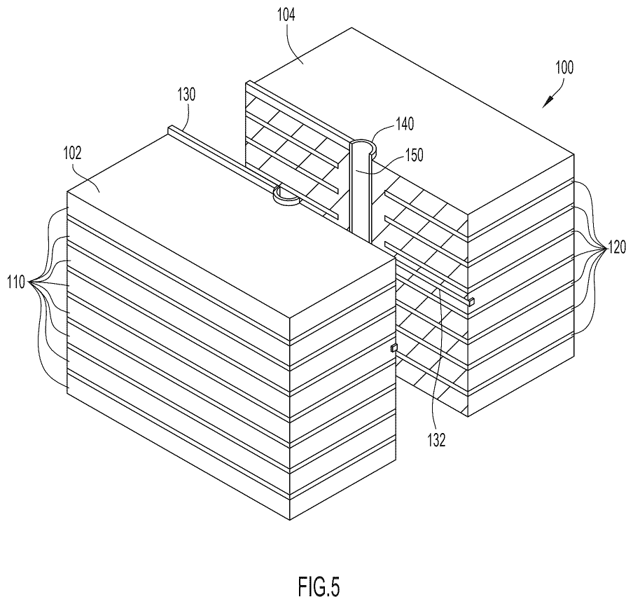

Referring to FIG. 5, a top perspective view of the PCB 100 is illustrated. In FIG. 5, the PCB 100 has been separated into two pieces 102 and 104, which are spaced apart from each other to show the inner components of the PCB 100.

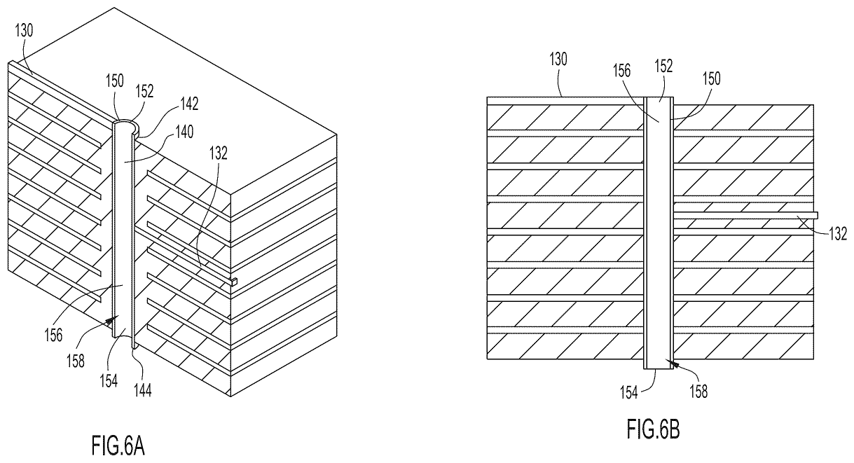

Turning to FIGS. 6A and 6B, a top perspective view and a side view, respectively, of the PCB 100 are illustrated. As shown, the high-speed traces 130 and 132 are visible in FIGS. 6A and 6B. In this embodiment, each of the high-speed traces 130 and 132 is connected to the plating of the VIA 140.

The VIA 140 has an upper end 142 and a lower end 144 opposite to the upper end 142. At this stage of the manufacturing process, the VIA 140 has a plating 150 along the inner surface of the VIA 140. The plating 150 has an upper end 152 and a lower end 154 opposite to the upper end 152. The plating 150 also has an inner surface 156 extending therealong that defines a channel 158 that extends from the upper end 152 to the lower end 154. At this point, the channel 158 is filled with air.

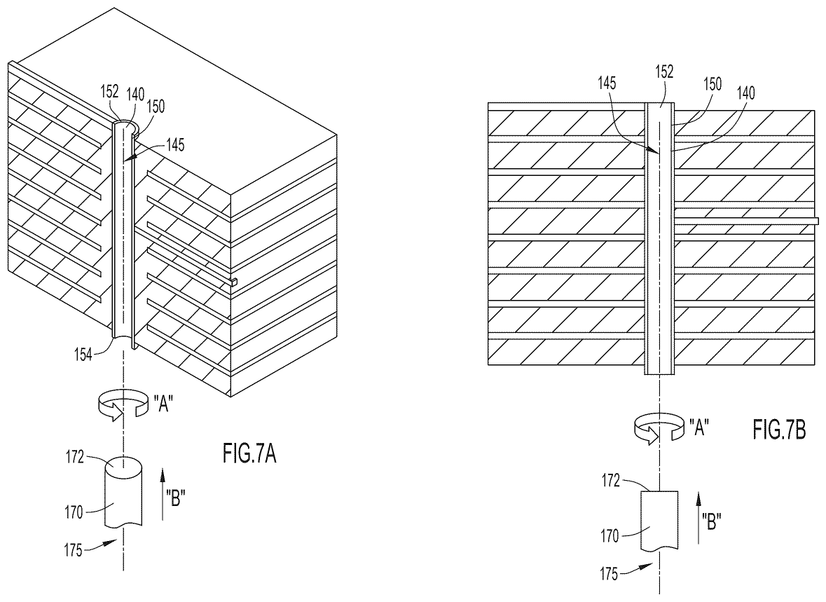

Referring to FIGS. 7A and 7B, a top perspective view and a side view, respectively, of the PCB 100 are illustrated. FIGS. 7A and 7B illustrate the next manufacturing step of preparing to backdrill a portion of the VIA 140. The VIA 140 has a longitudinal axis 145 that extends along the VIA 140 from its upper end 142 to its lower end 144.

In the step shown in FIGS. 7A and 7B, a drilling device 170, such as a drill bit, is oriented so that a longitudinal axis 175 of the drilling device 170 is aligned with the longitudinal axis 145 of the VIA 140. The drilling device 170 has a distal end 172 that is positioned so that it approaches the lower end 154 of the plating 150. The drilling device 170 is rotatable along arrow “A” about longitudinal axis 175, and can be moved along the direction of arrow “B” toward the VIA 140 by a tool or machine (not shown).

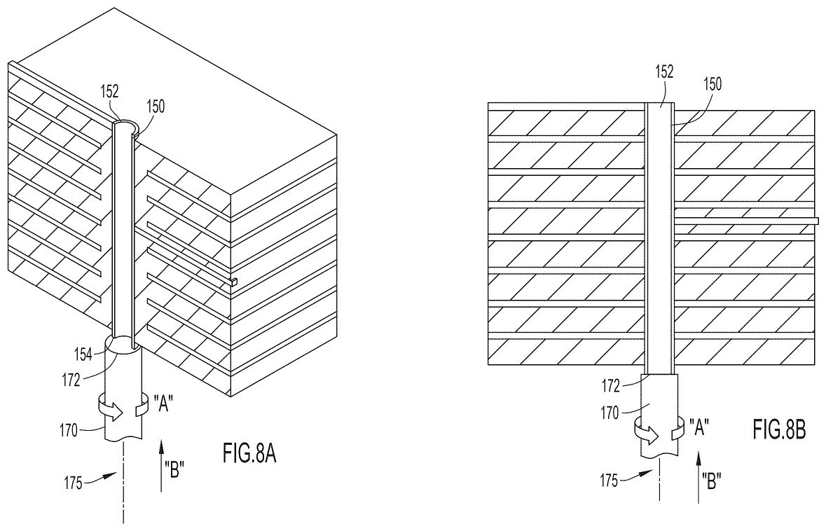

Turning to FIGS. 8A and 8B, a top perspective view and a side view, respectively, of the PCB 100 are illustrated showing the next manufacturing step. In this step, the drilling device 170 is advanced along the direction of arrow “B” so that the distal end 172 of the drilling device 170 contacts and engages the lower end 154 of the plating 150 in the VIA 140.

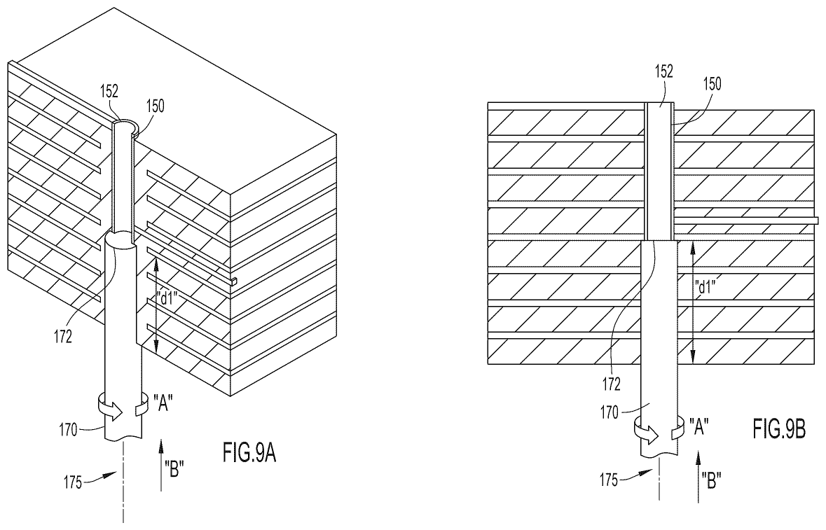

Turning to FIGS. 9A and 9B, a top perspective view and a side view, respectively, of the PCB 100 are illustrated showing the next manufacturing step. In this step, the drilling device 170 has been advanced along the direction of arrow “B” a distance “d1” into the VIA 140. As the drilling device 170 rotates along the direction of arrow “A” and moves along the direction of arrow “B”, a portion of the plating 150 is removed from the VIA 140 due to the movement of the drilling device 170, which is the backdrilling process.

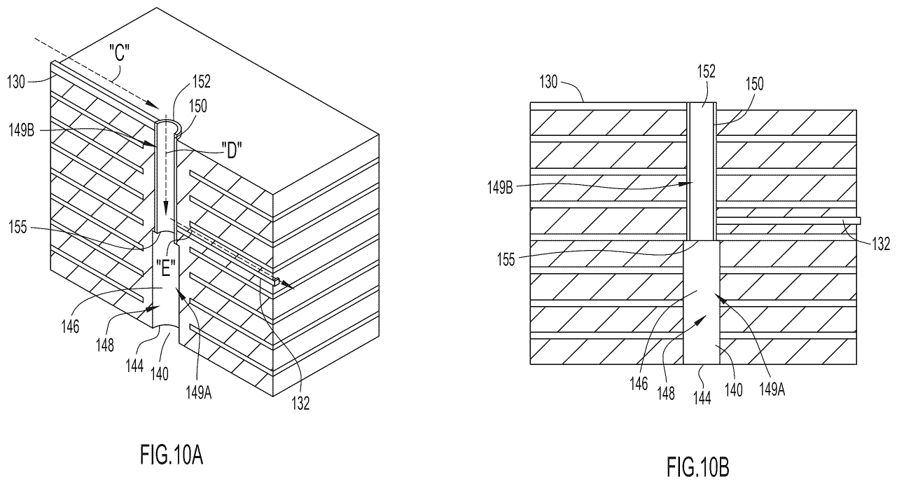

Turning to FIGS. 10A and 10B, a top perspective view and a side view, respectively, of the PCB 100 resulting from the step illustrated in FIGS. 9A and 9B are shown. The backdrilling process results in the plating 150 extending from its upper end 152 to an intermediate end 155, which is located at a position between the upper end 152 and the previously illustrated lower end 154 of the plating 150. As shown, a portion of the plating 150 has been removed by the backdrilling process, which results in the VIA 140 having a backdrilled portion 149A and a non-backdrilled portion 149B. The backdrilled portion 149A of the VIA 140 reveals the inner surface 146 of the VIA 140 which defines the channel 148 of the VIA 140.

In this implementation, the intermediate end 155 of the plating 150 resulting from the backdrilling is located below the connection of high-speed trace 132 to the plating 150 of the VIA 140. High-speed traces 130 and 132 are both connected to the plating 150. A signal can travel along the direction of arrow “C” along high-speed trace 130, along the direction of arrow “D” along plating 150, and then along the direction of arrow “E” along high-speed trace 132.

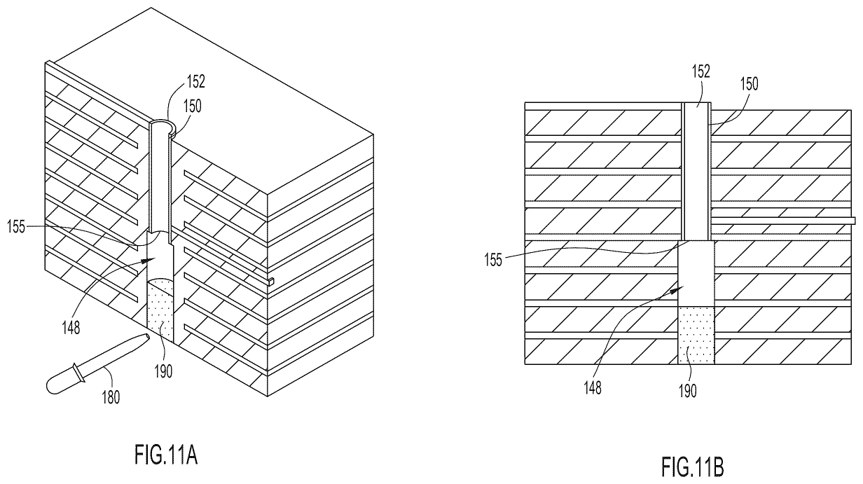

Turning to FIGS. 11A and 11B, a top perspective view and a side view, respectively, of PCB 100 showing the next manufacturing step are illustrated. In this manufacturing step, a supplying device 180 that contains a filling material 190 is positioned proximate to the lower end 144 of the VIA 140. The supplying device 180 is actuated to insert the filling material 190 into the backdrilled portion 149A, and in particular, into the channel 148 of the VIA 140.

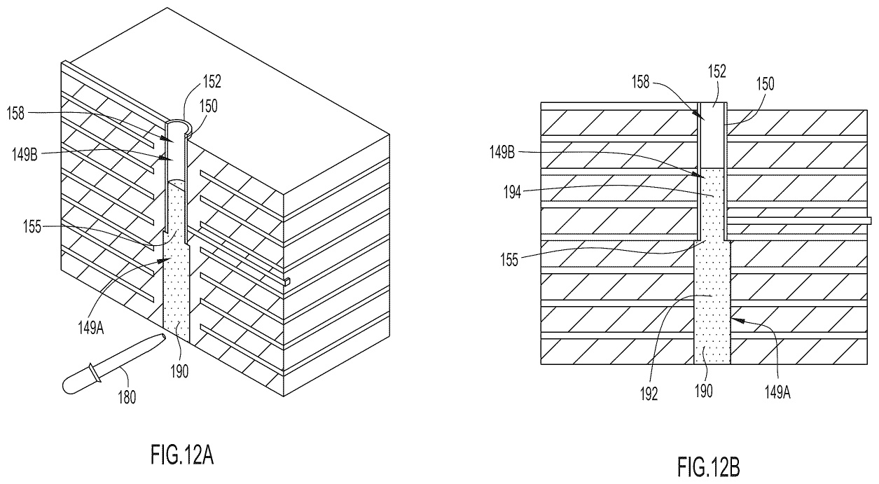

In FIGS. 12A and 12B, an intermediate filling step is illustrated. As shown, the filling material 190 continually inserted into the VIA 140. The filling material 190 moves from the backdrilled portion 149A into the non-backdrilled portion 149B as more filling material is supplied.

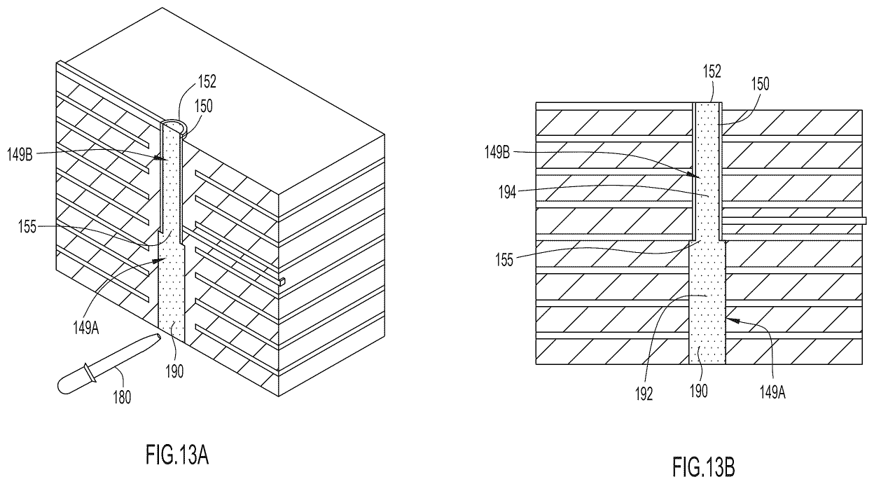

Referring to FIGS. 13A and 13B, a top perspective view and a side view, respectively, of PCB 100 showing the next manufacturing step are illustrated. In this manufacturing step, the supplying device 180 continues to provide additional filling material 190 into the VIA 140. As shown, a sufficient amount of filling material 190 is inserted into the VIA 140 so that the entire VIA 140 is filled with the filling material 190. In particular, the filling material 190 fills up the backdrilled portion 149A of the VIA 140 and the non-backdrilled portion 149B of the VIA 140.

As shown in FIG. 13B, the filling material 190 has two portions in the VIA 140. The filling material 190 has a lower portion 192 located in the backdrilled portion 149A and an upper portion 194 located in the non-backdrilled portion 149B.

In some aspects, the techniques described herein relate to a printed circuit board, comprising at least one layer; a VIA extending through the at least one layer, the VIA being backdrilled and filled with a backdrill filling material; and at least one trace connected to the VIA, wherein the backdrill filling material is selected based on backdrill filling material dielectric constant (“dk”) properties to reduce impedance mismatches at a transition between the VIA and the at least one trace.

In one aspect, the backdrill filling material is selected based on its dk properties to improve insertion loss in the PCB.

In another aspect, the backdrill filling material is selected based on its dk properties to improve return loss in the PCB.

In yet another aspect, the backdrill filling material is selected based on its dk properties to reduce signal reflections between the VIA and the at least one trace.

In one aspect, the backdrill filling material has a dk less than 4.4.

In a further aspect, the backdrill filling material has a dk of 3.5 or less.

In another further aspect, the backdrill filling material has a dk of 2.5 or less.

In another aspect, the backdrill filling material is selected based on its dk properties to reduce signal reflections between the VIA and the at least one trace, and to improve return loss in the PCB.

In yet another aspect, the VIA is a high-speed VIA, and the at least one trace is a high-speed trace.

In some aspects, the techniques described herein relate to a printed circuit board, comprising at least one layer; a high-speed VIA extending through the at least one layer; and at least one trace connected to the high-speed VIA, wherein the high-speed VIA is backdrilled and filled with a backdrill filling material that is selected based on backdrill filling material dk properties to minimize any effect of mismatch of impedances at a transition between the high-speed VIA and the at least one trace.

In one aspect, the backdrill filling material is selected based on its dk properties to improve insertion loss in the printed circuit board.

In an alternative aspect, the backdrill filling material is selected based on its dk properties to improve return loss in the printed circuit board.

In another aspect, the backdrill filling material is selected based on its dk properties to reduce signal reflections between the high-speed VIA and the at least one trace.

In one aspect, the backdrill filling material has a dk less than 4.4.

In a further aspect, the backdrill filling material has a dk of 3.5 or less.

In another further aspect, the backdrill filling material has a dk of 2.5 or less.

In some aspects, the techniques described herein relate to a printed circuit board, comprising at least one layer; a high-speed VIA extending through the at least one layer; and at least one trace connected to the high-speed VIA, wherein the high-speed VIA is backdrilled and filled with a backdrill filling material that is selected based on backdrill filling material dk properties to minimize any mismatching of impedances between the high-speed VIA and the at least one trace.

In one aspect, the backdrill filling material is selected based on its dk properties to improve either insertion loss or return loss in the printed circuit board.

In another aspect, the backdrill filling material is selected based on its dk properties to reduce signal reflections between the high-speed VIA and the at least one trace. In yet another aspect, the backdrill filling material has a dk less than 4.4.

### Variations and Implementations

Note that in this specification, references to various features (e.g., elements, structures, nodes, modules, components, engines, logic, steps, operations, functions, characteristics, etc.) included in “one embodiment,” “example embodiment,” “an embodiment,” “another embodiment,” “certain embodiments,” “some embodiments,” “various embodiments,” “other embodiments,” “alternative embodiment,” and the like are intended to mean that any such features are included in one or more embodiments of the present disclosure, but may or may not necessarily be combined in the same embodiments.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase “at least one of,” “one or more of,” “and/or,” variations thereof, or the like are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms “first,” “second,” “third,” etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A printed circuit board (PCB), comprising:
at least one layer;
a VIA extending through the at least one layer, the VIA being backdrilled and filled with a backdrill filling material; and
at least one trace connected to the VIA, wherein the backdrill filling material is selected based on backdrill filling material dielectric constant (“dk”) properties to reduce impedance mismatches at a transition between the VIA and the at least one trace.

2. The printed circuit board of claim 1, wherein the backdrill filling material is selected based on its dk properties to improve insertion loss in the PCB.

3. The printed circuit board of claim 1, wherein the backdrill filling material is selected based on its dk properties to improve return loss in the PCB.

4. The printed circuit board of claim 1, wherein the backdrill filling material is selected based on its dk properties to reduce signal reflections between the VIA and the at least one trace.

5. The printed circuit board of claim 1, wherein the backdrill filling material has a dk less than 4.4.

6. The printed circuit board of claim 5, wherein the backdrill filling material has a dk of 3.5 or less.

7. The printed circuit board of claim 6, wherein the backdrill filling material has a dk of 2.5 or less.

8. The printed circuit board of claim 1, wherein the backdrill filling material is selected based on its dk properties to reduce signal reflections between the VIA and the at least one trace, and to improve return loss in the PCB.

9. The printed circuit board of claim 1, wherein the VIA is a high-speed VIA, and the at least one trace is a high-speed trace.

10. A printed circuit board, comprising:
at least one layer;
a high-speed VIA extending through the at least one layer; and
at least one trace connected to the high-speed VIA, wherein the high-speed VIA is backdrilled and filled with a backdrill filling material that is selected based on backdrill filling material dk properties to minimize any effect of mismatch of impedances at a transition between the high-speed VIA and the at least one trace.

11. The printed circuit board of claim 10, wherein the backdrill filling material is selected based on its dk properties to improve insertion loss in the printed circuit board.

12. The printed circuit board of claim 10, wherein the backdrill filling material is selected based on its dk properties to improve return loss in the printed circuit board.

13. The printed circuit board of claim 10, wherein the backdrill filling material is selected based on its dk properties to reduce signal reflections between the high-speed VIA and the at least one trace.

14. The printed circuit board of claim 10, wherein the backdrill filling material has a dk less than 4.4.

15. The printed circuit board of claim 14, wherein the backdrill filling material has a dk of 3.5 or less.

16. The printed circuit board of claim 15, wherein the backdrill filling material has a dk of 2.5 or less.

17. A printed circuit board, comprising:
at least one layer;
a high-speed VIA extending through the at least one layer; and
at least one trace connected to the high-speed VIA, wherein the high-speed VIA is backdrilled and filled with a backdrill filling material that is selected based on backdrill filling material dk properties to minimize any mismatching of impedances between the high-speed VIA and the at least one trace.

18. The printed circuit board of claim 17, wherein the backdrill filling material is selected based on its dk properties to improve either insertion loss or return loss in the printed circuit board.

19. The printed circuit board of claim 17, wherein the backdrill filling material is selected based on its dk properties to reduce signal reflections between the high-speed VIA and the at least one trace.

20. The printed circuit board of claim 17, wherein the backdrill filling material has a dk less than 4.4.
